(19) United States
(12) Patent Application Publication
(10) Pub. No.: US 2025/0015043 A1
(43) Pub. Date: Jan. 9, 2025

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventors: Jaeean LEE, Suwon-si (KR); Dongwon KANG, Suwon-si (KR); Changyeon SONG, Suwon-si (KR); Sunguk LEE, Suwon-si (KR)

(21) Appl. No.: 18/748,295

(22) Filed: Jun. 20, 2024

(30) Foreign Application Priority Data
Jul. 4, 2023 (KR) 10-2023-0086719

(51) Int. Cl. H01L 23/00; H01L 23/31; H01L 23/498

(52) U.S. Cl. CPC H01L 24/82; H01L 23/3107; H01L 23/49822; H01L 23/49827; H01L 24/08; H01L 24/24; H01L 24/97; H01L 23/49816; H01L 2224/08225; H01L 2224/82005

(57) ABSTRACT

A semiconductor package includes: a first redistribution structure including a first upper connection pad and a first lower connection pad; a first semiconductor device on the first redistribution structure; a vertical connection conductor on the first redistribution structure; an encapsulant adjacent to the first semiconductor device; a second redistribution structure on the encapsulant and including a second redistribution pattern, a second insulating layer, a second upper connection pad, and a second lower connection pad; an insulating adhesive layer between the second redistribution structure and the encapsulant; and an intermediate connection terminal connecting the second lower connection pad with the vertical connection conductor, wherein the second upper connection pad is exposed by an upper opening of the second insulating layer. A cover conductive layer is on the second upper connection pad. A side surface of the intermediate connection terminal is covered with the insulating adhesive layer and the encapsulant.

### CROSS-REFERENCE TO RELATED APPLICATION

This application claims priority under 35 U.S.C. § 119 to Korean Patent Application No. 10-2023-0086719, filed on Jul. 4, 2023, in the Korean Intellectual Property Office, the disclosure of which is incorporated by reference herein in its entirety.

### TECHNICAL FIELD

Embodiments of the present inventive concept relate to a semiconductor package and a method of manufacturing the semiconductor package.

### DISCUSSION OF THE RELATED ART

The demand for portable devices has rapidly increased in electronic product markets, and thus, the size reduction and weight reduction of electronic components, which are incorporated in such electronic products, have been continuously desired. To achieve the size reduction and weight reduction of electronic components, it is desirable for semiconductor packages that are disposed in the electronic components to process large amounts of data as well as to be gradually reduced in volume. Recently, panel-level package (PLP) technology, in which semiconductor package processes are performed at a panel level and a panel-level semiconductor structure having undergone semiconductor package processes is separated into individual packages, has been under development.

### SUMMARY

According to an embodiment of the present inventive concept, a semiconductor package includes: a first redistribution structure, which includes a first upper connection pad and a first lower connection pad, wherein the first upper connection pad is disposed on an upper surface of the first redistribution structure, and wherein the first lower connection pad is disposed on a lower surface of the first redistribution structure; a first semiconductor device mounted on the first redistribution structure; a vertical connection conductor, which is spaced apart from the first semiconductor device and arranged on the first redistribution structure; an encapsulant at least partially surrounding the first semiconductor device; a second redistribution structure arranged on the encapsulant and including a second redistribution pattern and a second insulating layer, wherein the second redistribution structure further includes a second upper connection pad and a second lower connection pad, wherein the second upper connection pad is disposed on an upper surface of the second redistribution structure, and the second lower connection pad is disposed on a lower surface of the second redistribution structure; an insulating adhesive layer arranged between the second redistribution structure and the encapsulant, which are apart from each other; and an intermediate connection terminal connecting the second lower connection pad with the vertical connection conductor, wherein at least a portion of the second upper connection pad is exposed from the second insulating layer by an upper opening of the second insulating layer, a cover conductive layer is arranged on the second upper connection pad, a portion of a side surface of the intermediate connection terminal is covered with the insulating adhesive layer, and the remaining portion of the side surface of the intermediate connection terminal is covered with the encapsulant.

According to an embodiment of the present inventive concept, a method of manufacturing a semiconductor package includes: a first process including: forming a first structure, which includes a first semiconductor device and a first redistribution structure, on each of two sides of a first detached copper foil (DCF) carrier; and separating the first DCF carrier into two halves in both side directions of the first DCF carrier; a second process including: forming a second structure, which includes a second redistribution structure, on each of two sides of a second DCF carrier; and separating the second DCF carrier into two halves in both side directions of the second DCF carrier; and a third process including attaching the first structure and the second structure to each other.

According to an embodiment of the present inventive concept, a method of manufacturing a semiconductor package includes: a first process including: forming a first structure, which includes a first semiconductor device and a first redistribution structure, on each of two sides of a first detached copper foil (DCF) carrier; and separating the first DCF carrier into two halves in different directions of each other. The method further includes a second process including: forming a second structure, which includes a second redistribution structure, on each of two sides of a second DCF carrier; and separating the second DCF carrier into two halves in different directions of each other. The method further includes a third process of attaching the first structure and the second structure to each other. The first process further includes: arranging, on a tape carrier, a vertical connection conductor, a substrate base, which surrounds the vertical connection conductor, and a first semiconductor device that is laterally spaced apart from the substrate base; forming an encapsulant that at least partially surrounds the first semiconductor device; arranging the vertical connection conductor and the first semiconductor device, which are arranged on the tape carrier, on each of the two sides of the first DCF carrier; forming the first structure, which includes the first semiconductor device and the first redistribution structure, on each of the two sides of the first DCF carrier by removing the tape carrier and by forming the first redistribution structure on a surface from which the tape carrier is removed; separating the first DCF carrier into two halves in different directions of each other and arranging the first structure on a first carrier; and forming an intermediate opening in the encapsulant by recessing the encapsulant, wherein the intermediate opening exposes a portion of a wiring pattern that is arranged on the vertical connection conductor. The second process further includes: forming a second redistribution insulating layer on each of the two sides of the second DCF carrier; forming a cover conductive layer on a portion of the second redistribution insulating layer; forming a second upper connection pad pattern on the cover conductive layer and a portion of the second redistribution insulating layer; forming the second redistribution structure; separating the second DCF carrier into two halves in different directions of each other; forming an intermediate connection terminal on the second lower connection pad; and forming an insulating adhesive layer on a lower surface of the second redistribution structure, and wherein the third process further includes: mounting the second structure on the first structure; removing the first carrier and the second DCF carrier from the first structure and the second structure, respectively; removing a copper foil that is on each of the first structure and the second structure; forming an upper opening by recessing a portion of an upper surface of the second redistribution structure, wherein the upper opening exposes at least a portion of the cover conductive layer; and forming a first external connection terminal on a lower surface of the first redistribution structure.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view illustrating a semiconductor package according to an embodiment of the present inventive concept;

FIG. 2 is a cross-sectional view illustrating a semiconductor package according to an embodiment of the present inventive concept;

FIG. 3 is a flowchart illustrating a method of manufacturing a semiconductor package, according to an embodiment of the present inventive concept;

FIG. 4 is a flowchart illustrating a first process of a method of manufacturing a semiconductor package, according to an embodiment of the present inventive concept;

FIGS. 5A, 5B, 5C, 5D, 5E, 5F, and 5G are cross-sectional views illustrating a first process of a method of manufacturing a semiconductor package, according to an embodiment of the present inventive concept;

FIG. 6 is a flowchart illustrating a second process of a method of manufacturing a semiconductor package, according to an embodiment of the present inventive concept;

FIGS. 7A, 7B, 7C, 7D, 7E, and 7F are cross-sectional views illustrating a second process of a method of manufacturing a semiconductor package, according to an embodiment of the present inventive concept;

FIG. 8 is a flowchart illustrating a third process of a method of manufacturing a semiconductor package, according to an embodiment of the present inventive concept; and

FIGS. 9A, 9B, 9C, and 9D are cross-sectional views illustrating a third process of a method of manufacturing a semiconductor package, according to an embodiment of the present inventive concept.

### DETAILED DESCRIPTION OF THE EMBODIMENTS

Hereinafter, embodiments of the present inventive concept will be described in detail with reference to the accompanying drawings. Like components are denoted by like reference numerals throughout the specification and drawings, and repeated descriptions thereof are omitted or briefly discussed.

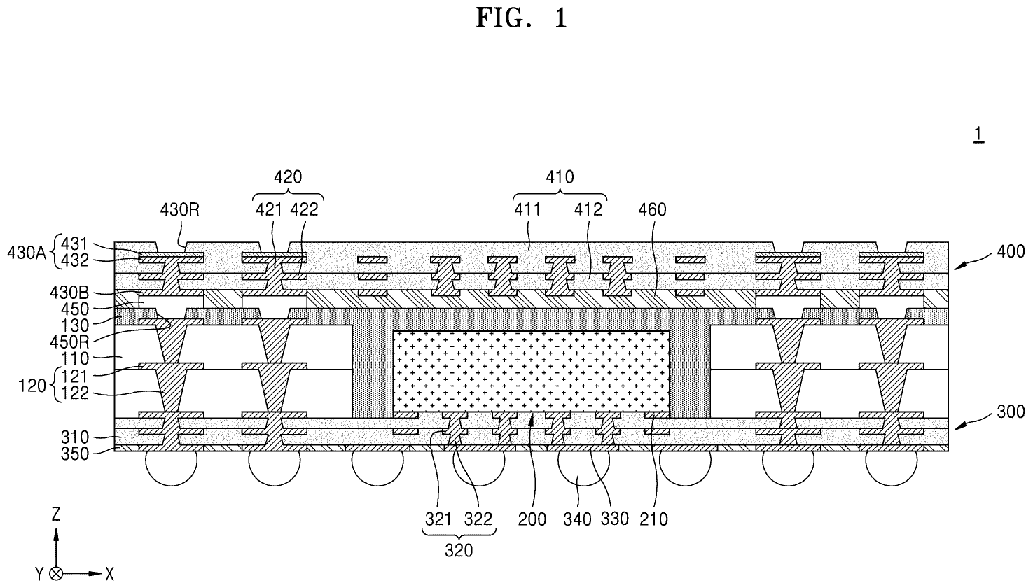

FIG. 1 is a cross-sectional view illustrating a semiconductor package 1 according to an embodiment of the present inventive concept.

Referring to FIG. 1, the semiconductor package 1 may include a first redistribution structure 300, at least one first semiconductor device 200 mounted on the first redistribution structure 300, a substrate base 110 that is laterally spaced apart from the first semiconductor device 200 and arranged on the first redistribution structure 300, a vertical connection conductor 122 passing through the substrate base 110, and a second redistribution structure 400 arranged on the substrate base 110 and the first semiconductor device 200. Herein, the substrate base 110 may be referred to as a substrate.

The semiconductor package 1 may include a fan-out semiconductor package. In embodiments of the present inventive concept, the substrate base 110 may include a panel board, and the semiconductor package 1 may include a fan-out panel level package (FOPLP). As used herein, the term “horizontal” refers to the X-Y plane. The term “first horizontal direction” refers to the X direction, and the term “second horizontal direction” refers to the Y direction. As used herein, the term “vertical” refers to a direction perpendicular or substantially perpendicular to the X-Y plane, and the term “vertical direction” refers to the Z direction.

The first semiconductor device 200 may include a semiconductor substrate having an active surface, on which a semiconductor device is formed, and a plurality of chip connection pads 210 arranged on the active surface of the semiconductor substrate. The semiconductor substrate may include, for example, a semiconductor material, such as silicon (Si). In addition, the semiconductor substrate may include a semiconductor element, such as germanium (Ge), or a compound semiconductor, such as silicon carbide (SiC), gallium arsenide (GaAs), indium arsenide (InAs), and indium phosphide (InP). The semiconductor substrate may include a conductive region, for example, an impurity-doped well. The semiconductor substrate may include various device isolation structures, such as a shallow trench isolation (STI). Herein, the first semiconductor device 200 may be referred to as a semiconductor chip.

A semiconductor device including a plurality of individual devices of various types may be formed on the active surface of the semiconductor substrate. The plurality of individual devices may include various microelectronic devices, for example, a metal-oxide-semiconductor field effect transistor (MOSFET), such as a complementary metal-insulator-semiconductor (CMOS) transistor, a system large-scale integration (LSI), an image sensor, such as a CMOS imaging sensor, a micro-electro-mechanical system (MEMS), an active element, a passive element, and the like.

The first semiconductor device 200 may include, for example, a central processing unit (CPU) chip, a graphics processing unit (GPU) chip, or an application processor (AP) chip. In embodiments of the present inventive concept, when the semiconductor package 1 includes a plurality of first semiconductor devices 200, at least some of the plurality of first semiconductor devices 200 may include, for example, dynamic random access memory (DRAM) chips, static random access memory (SRAM) chips, flash memory chips, electrically erasable and programmable read-only memory (EEPROM) chips, phase-change random access memory (PRAM) chips, magnetic random access memory (MRAM) chips, or resistive random access memory (RRAM) chips.

The first semiconductor device 200 may be mounted on the first redistribution structure 300. The first redistribution structure 300 may be referred to as a lower redistribution structure. In embodiments of the present inventive concept, the first redistribution structure 300 may be formed by a redistribution process. The first redistribution structure 300 may include a first redistribution insulating layer 310 and a plurality of first redistribution patterns 320. The first redistribution insulating layer 310 may at least partially surround the plurality of first redistribution patterns 320. In embodiments of the present inventive concept, the first redistribution structure 300 may include a plurality of first redistribution insulating layers 310 that are stacked on each other. For example, the first redistribution structure 300 may include a first redistribution insulating layer, which is adjacent to the first semiconductor device 200, and a second redistribution insulating layer that is disposed on the first redistribution insulating layer. For example, the first redistribution structure 300 may include two or more redistribution insulating layers.

The lower surface of the first semiconductor device 200 may be disposed on the uppermost first redistribution insulating layer 310 from among the plurality of first redistribution insulating layers 310. For example, the lower surface of the first semiconductor device 200 may be in direct contact with the uppermost first redistribution insulating layer 310 from among the plurality of first redistribution insulating layers 310. In a method S1 of manufacturing a semiconductor package, which corresponds to a process of manufacturing the semiconductor package 1, according to an embodiment of the present inventive concept as described below, the first redistribution structure 300 may be formed on the first semiconductor device 200 by a chip-first process.

The first redistribution insulating layer 310 may include, for example, a material film including an organic compound. In embodiments of the present inventive concept, at least one lower redistribution insulating layer 310 may include a material film including an organic polymer material. In embodiments of the present inventive concept, the first redistribution insulating layer 310 may include a photosensitive polyimide (PSPI). The first redistribution insulating layer 310 may include, for example, a photo-imageable dielectric. The first redistribution insulating layer 310 may include, for example, a photosensitive polymer. The photosensitive polymer may include, for example, at least one of a PSPI, polybenzoxazole, a phenol-based polymer, and/or a benzocyclobutene-based polymer.

The plurality of first redistribution patterns 320 may include a plurality of first redistribution line patterns 321 and a plurality of first redistribution via patterns 322. Each of the plurality of first redistribution patterns 320 may include, but is not limited to, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), or ruthenium (Ru), or an alloy thereof.

The plurality of first redistribution line patterns 321 may be arranged on at least one of the upper or lower surfaces of the first redistribution insulating layer 310. For example, at least a portion of the uppermost first redistribution line patterns 321 from among the plurality of first redistribution line patterns 321 may correspond to first upper connection pads, and at least a portion of the lowermost first redistribution line patterns 321 from among the plurality of first redistribution line patterns 321 may correspond to first lower connection pads. The plurality of first redistribution via patterns 322 may pass through the first redistribution insulating layer 310 and be respectively connected with the plurality of first redistribution line patterns 321. Each of the plurality of first redistribution via patterns 322 may have a tapered shape, which extends with an increasing horizontal width away from the first semiconductor device 200.

In embodiments of the present inventive concept, some of the plurality of first redistribution line patterns 321 may be formed together with and thus integrated with some of the plurality of first redistribution via patterns 322. For example, a first redistribution line pattern 321 may be formed together with and thus integrated with a first redistribution via pattern 322, which is in contact with the lower surface of the first redistribution line pattern 321. For example, a first redistribution line pattern 321 may be formed together with and thus integrated with a first redistribution via pattern 322, which is in contact with the lower surface of the first redistribution line pattern 321, and another first redistribution via pattern 322, which is in contact with the upper surface of the first redistribution line pattern 321.

A chip connection pad 210 of the first semiconductor device 200 may be electrically connected with the first redistribution structure 300. The first redistribution insulating layer 310, which constitutes the first redistribution structure 300, may be in contact with the lower surface of the first semiconductor device 200. In embodiments of the present inventive concept, a portion of the uppermost first redistribution via pattern 322, from among the plurality of first redistribution via patterns 322, may be in contact with the chip connection pad 210, but the present inventive concept is not limited thereto. In embodiments of the present inventive concept, a portion of the uppermost first redistribution line pattern 321, from among the plurality of first redistribution line patterns 321, may be in contact with the chip connection pad 210. An external connection terminal 340, which is electrically connected with a wiring structure 120 and the first semiconductor device 200, may be attached to a lower portion of the first redistribution structure 300. In embodiments of the present inventive concept, at least a portion of the lowermost first redistribution line pattern 321, from among the plurality of first redistribution line patterns 321, may correspond to an external connection pad 330 that is attached to the external connection terminal 340. A lower protective layer 350 may be arranged on the lower surface of the lowermost first redistribution insulating layer 310 to constitute the first redistribution structure 300.

The substrate base 110 and the wiring structure 120 may be arranged on the first redistribution structure 300 to be laterally spaced apart from the first semiconductor device 200. The wiring structure 120 may include a wiring pattern 121 and a vertical connection conductor 122. The wiring structure 120 may include, for example, copper, nickel, stainless steel, and/or beryllium copper. The wiring structure 120 may be electrically connected with the first redistribution pattern 320 of the first redistribution structure 300 and with a second redistribution pattern 420 of a second redistribution structure 400 described below.

The substrate base 110 may include at least one of a phenol resin, an epoxy resin, and/or polyimide. The substrate base 110 may include, for example, at least one of Flame Retardant 4 (FR-4), tetrafunctional epoxy, polyphenylene ether, epoxy/polyphenylene oxide, bismaleimide triazine (BT), Thermount, cyanate ester, polyimide, and/or a liquid crystal polymer.

In embodiments of the present inventive concept, the substrate base 110 may be provided as a multilayered substrate including a plurality of substrate bases 110 as a plurality of layers. Wiring patterns 121 may be respectively arranged between the plurality of substrate bases 110 and on at least some of the upper and lower surfaces of the plurality of substrate bases 110.

To electrically connect the wiring patterns 121 respectively arranged in different wiring layers to each other, the semiconductor package 1 may further include a plurality of vertical connection conductors 122, each of which pass through at least a portion of the substrate base 110. In embodiments of the present inventive concept, the semiconductor package 1 may include a number of wiring layers that is one more than the number of substrate bases 110.

The semiconductor package 1 may further include an encapsulant 130 filling spaces between the first semiconductor device 200 and the second redistribution structure 400, which is described below, and between the first semiconductor device 200 and the substrate base 110. The encapsulant 130 may cover the upper surface of the uppermost substrate base 110, from among the plurality of substrate bases 110, and the upper surface of the first semiconductor device 200. For example, the encapsulant 130 may include a thermosetting resin such as an epoxy resin, a thermoplastic resin such as polyimide, or a resin obtained by adding a complement material such as an inorganic filler to a thermosetting resin or a thermoplastic resin, for example, Ajinomoto Build-up Film (ABF), FR-4, BT, or the like. In addition, the encapsulant 130 may include a molding material, such as an epoxy molding compound (EMC), or a photosensitive material, such as a photo-imageable encapsulant (PIE). In embodiments of the present inventive concept, a portion of the encapsulant 130 may include an insulating material, such as a silicon oxide film, a silicon nitride film, or a silicon oxynitride film. The encapsulant 130 may be referred to as a cover insulating layer.

Some of the wiring patterns 121 of the wiring structure 120 may correspond to intermediate connection pads arranged on the uppermost substrate base 110. Each of the intermediate connection pads may be connected with the vertical connection conductor 122 and be electrically connected with the first redistribution pattern 320 of the first redistribution structure 300.

An intermediate opening 450R may be formed by recessing a portion of the encapsulant 130, and at least a portion of an intermediate connection pad may be exposed from the encapsulant 130 by the intermediate opening 450R. For example, the intermediate opening 450R may be a hole in the encapsulant 130. An intermediate connection terminal 450 may be arranged on the intermediate connection pad that is exposed from the encapsulant 130.

The intermediate connection terminal 450 may connect a second lower connection pad 430B, which is arranged on a lower surface of the second redistribution structure 400 that is described below, with the intermediate connection pad that is a portion of the wiring patterns 121. For example, the second redistribution pattern 420 of the second redistribution structure 400 may be electrically connected with the first redistribution pattern 320 of the first redistribution structure 300 via the intermediate connection terminal 450.

The intermediate connection terminal 450 may include a low-temperature solder ball or a conductive paste. Each of the low-temperature solder ball and the conductive paste may have a melting point of about 200° C. or less. The low-temperature solder ball may include, for example, tin (Sn), bismuth (Bi), and zinc (Zn). The conductive paste may include, for example, silver (Ag) and a thermosetting resin.

As described below in the method S1 of manufacturing a semiconductor package, according to an embodiment of the present inventive concept, because, via the intermediate connection terminal 450, which includes the low-temperature solder ball or the conductive paste, a first structure may be mounted on a second structure at a relatively lower temperature than that of a general thermocompression method, and the warpage of a semiconductor package due to heating during bonding may be reduced. In addition, because thermocompression is performed at a relatively low temperature, the peeling of other components due to heat may be prevented.

A portion of the side surface of the intermediate connection terminal 450 may be covered by the encapsulant 130. For example, a portion of the side surface of the intermediate connection terminal 450 may be in contact with the encapsulant 130, and the remaining portion of the side surface of the intermediate connection terminal 450 may be in contact with an insulating adhesive layer 460. Because, during bonding, the intermediate connection terminal 450 is in contact with the intermediate connection pad that is at least partially exposed by the intermediate opening 450R, a portion of the intermediate connection terminal 450 may have a shape that is in complementary contact with the shape of the intermediate opening 450R. For example, the side surface of the intermediate connection terminal 450 may be in contact with the encapsulant 130 and the insulating adhesive layer 460.

The semiconductor package 1 according to an embodiment of the present inventive concept may include the insulating adhesive layer 460 arranged on the encapsulant 130. In addition, the semiconductor package 1 according to an embodiment of the present inventive concept may include the second redistribution structure 400 arranged on the insulating adhesive layer 460. The second redistribution structure 400 may be referred to as an upper redistribution structure.

The lower surface of the insulating adhesive layer 460 may be disposed on the upper surface of the encapsulant 130. For example, the lower surface of the insulating adhesive layer 460 may be in contact with the upper surface of the encapsulant 130, and the insulating adhesive layer 460 may be arranged between the encapsulant 130 and the lowermost second redistribution insulating layer 410 from among a plurality of second redistribution insulating layers 410. For example, the insulating adhesive layer 460 may be distinguished from the encapsulant 130 and the second redistribution insulating layer 410. For example, the insulating adhesive layer 460 may include a material different from that of the encapsulant 130 and the second redistribution insulating layer 410; however, the present inventive concept is not limited thereto. As described below in the method S1 of manufacturing a semiconductor package, according to an embodiment of the present inventive concept, the insulating adhesive layer 460 may allow the second structure, which includes the second redistribution structure 400, to be attached onto and mounted on the first structure, which includes the first semiconductor device 200, the first redistribution structure 300, and the wiring structure 120. For example, the insulating adhesive layer 460 may include a nonconductive film (NCF) or a nonconductive adhesive (NCA).

The second redistribution structure 400 may be arranged on the insulating adhesive layer 460. The second redistribution structure 400 may include at least one second redistribution insulating layer 410, the second redistribution pattern 420, and the insulating adhesive layer 460. The second redistribution pattern 420 may include a plurality of second redistribution line patterns 422, which are each arranged on at least one of the upper or lower surfaces of the at least one second redistribution insulating layer 410, and a plurality of second redistribution via patterns 421, which are respectively in contact and connected with at least some of the plurality of second redistribution line patterns 422 through at least a portion of the at least one second redistribution insulating layer 410. The second redistribution insulating layer 410 may include a second uppermost insulating layer 411 and a second lowermost insulating layer 412, but the number of insulating layers, which are included in the second redistribution insulating layer 410, is not limited thereto.

Because the second redistribution insulating layer 410 of the second redistribution structure 400 is substantially similar to the first redistribution insulating layer 310 of the first redistribution structure 300 and the second redistribution pattern 420 of the second redistribution structure 400, which includes the plurality of second redistribution line patterns 422 and the plurality of second redistribution via patterns 421, is substantially similar to the first redistribution pattern 320 of the first redistribution structure 300, which includes the plurality of first redistribution line patterns 321 and the plurality of first redistribution via patterns 322, repeated descriptions are omitted or briefly discussed.

At least some of the plurality of second redistribution line patterns 422 may be formed together with and integrated with at least some of the plurality of second redistribution via patterns 421. For example, some of the plurality of second redistribution line patterns 422 may be formed together with and integrated with some of the plurality of second redistribution via patterns 421, which are respectively in contact with lower portions of some of the plurality of second redistribution line patterns 422.

Each of the plurality of second redistribution via patterns 421 may have a tapered shape extending with an increasing horizontal width from top to bottom of each thereof. For example, the horizontal width of each of the plurality of second redistribution via patterns 421 may increase toward the first semiconductor device 200.

The uppermost second redistribution line pattern 422 from among the plurality of second redistribution line patterns 422 may correspond to a second upper connection pad 430A having an upper surface that is partially exposed rather than covered by the second redistribution insulating layer 410. For example, at least a portion of the second upper connection pad 430A may be exposed by an upper opening 430R, which is formed by recessing a portion of the second redistribution insulating layer 410. For example, the upper opening 430R may be a hole that is formed in the second uppermost insulating layer 411.

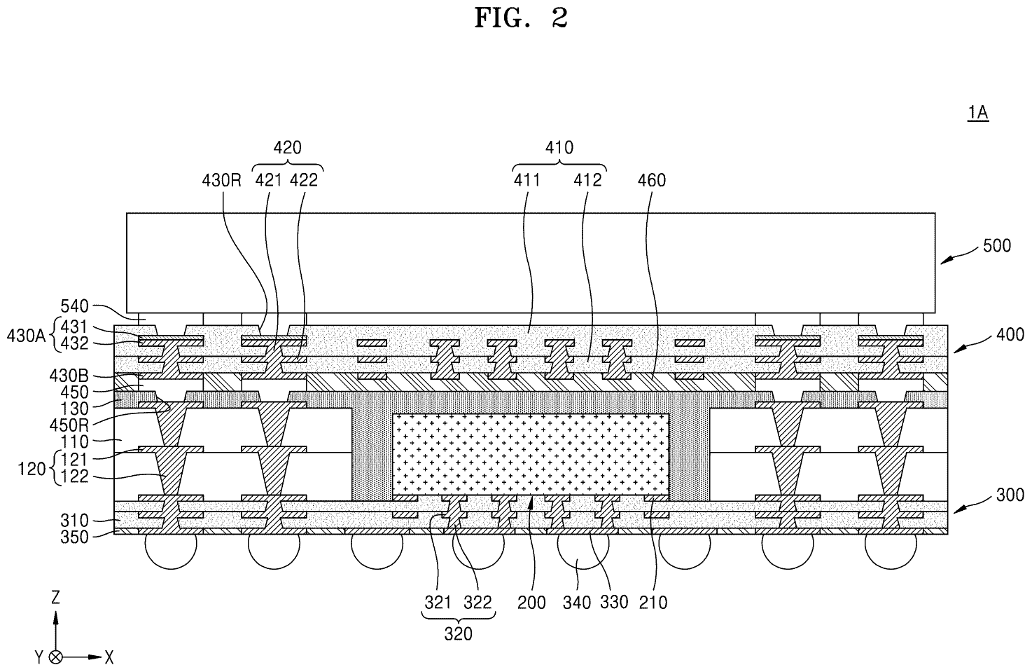

Each of the upper opening 430R and the intermediate opening 450R may conform to a solder mask defined (SMD) connection terminal connecting method. For example, the upper opening 430R may be formed such that at least a portion of the second upper connection pad 430A is covered by the second redistribution insulating layer 410 and thus not exposed. Likewise, the intermediate opening 450R may be formed such that a portion of the intermediate connection pad is not exposed by the encapsulant 130. Due to such a structure, because the alignment between an upper connection terminal 540, which is described below with reference to FIG. 2, and the second upper connection pad 430A and the alignment between the intermediate connection pad and the intermediate connection terminal 450 are easily performed, the reliability of the semiconductor package 1 may be increased.

The second upper connection pad 430A may include a cover conductive layer 431, which corresponds to a portion directly exposed to the outside of the second redistribution structure 400 by the upper opening 430R, and a second connection pad pattern 432, which corresponds to a portion directly connected with the second redistribution via pattern 421. When the cover conductive layer 431 is formed on the second connection pad pattern 432 and a second semiconductor device 500 is mounted on the cover conductive layer 431 by a package-on-package (POP) method as described below with reference to a semiconductor package 1A (see FIG. 2) according to an embodiment of the present inventive concept, the cover conductive layer 431 may be connected (e.g., directly connected) with the upper connection terminal 540 (see FIG. 2) allowing the cover conductive layer 431 to be electrically connected with the second semiconductor device 500 (see FIG. 2). In an embodiment of the present inventive concept, the cover conductive layer 431 may include at least one metal plating layer. The metal plating layer may include a metal including, for example, gold (Au). In an embodiment of the present inventive concept, the cover conductive layer 431 may include a first metal plating layer and a second metal plating layer. The first metal plating layer may be connected (e.g., directly connected) with the upper connection terminal 540 when the second semiconductor device 500 is mounted on the cover conductive layer 431. For example, the first metal plating layer may include gold (Au) and the second metal plating layer may include nickel (Ni).

A second lower connection pad 430B may be arranged on the second lowermost insulating layer 412 from among a plurality of insulating layers that are included in the second redistribution insulating layer 410. Second lower connection pads 430B may be respectively connected with at least some of the second redistribution via patterns 421. The second lower connection pad 430B may be arranged on the lower side of the plurality of second redistribution insulating layers 410 and connected (e.g., directly connected) with the intermediate connection terminal 450. For example, at least a portion of the side surface of the second lower connection pad 430B may be in contact with the insulating adhesive layer 460.

FIG. 2 is a cross-sectional view illustrating a semiconductor package 1A according to an embodiment of the present inventive concept. Repeated descriptions given with reference to FIG. 1 may be omitted.

Referring to FIG. 2, as described above, the second semiconductor device 500 may be mounted on the second redistribution structure 400. The cover conductive layer 431 may be connected with the upper connection terminal 540 which enables the cover conductive layer 431 to be electrically connected with the second semiconductor device 500. For example, the cover conductive layer 431 may be directly connected with the upper connection terminal 540. For example, the second semiconductor device 500 may be electrically connected to the second upper connection pad 430A via the upper connection terminal 540.

The second semiconductor device 500 may include, for example, a semiconductor package including at least one semiconductor chip. In embodiments of the present inventive concept, the semiconductor chip of the second semiconductor device 500 may include a logic device. For example, the semiconductor chip of the second semiconductor device 500 may include a CPU chip, a GPU chip, or an AP chip. In embodiments of the present inventive concept, one semiconductor chip of the second semiconductor device 500 may include a CPU chip, a GPU chip, or an AP chip and another semiconductor chip of the second semiconductor device 500 may include a memory semiconductor chip including a memory device.

For example, the memory device may include a nonvolatile memory device, such as flash memory, PRAM, MRAM, ferroelectric random access memory (FeRAM), or RRAM. In embodiments of the present inventive concept, the memory device may include a volatile memory device, such as DRAM or SRAM. In addition, the second semiconductor device 500 may include a semiconductor device in which a plurality of semiconductor chips are vertically stacked on each other. The plurality of semiconductor chips may include stacked semiconductor chips each including a through-silicon via (TSV).

The second semiconductor device 500 may transmit electrical signals to and receive electrical signals from a separate external device via the external connection terminal 340 and may be electrically connected with the first semiconductor device 200.

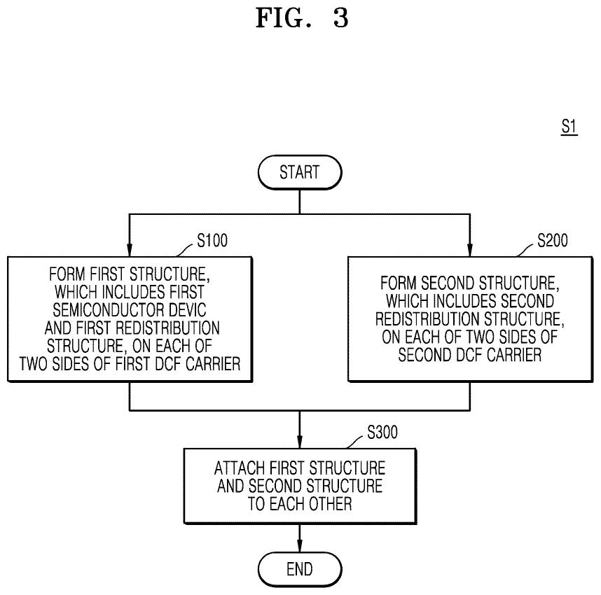

FIG. 3 is a flowchart illustrating a method S1 of manufacturing a semiconductor package, according to an embodiment of the present inventive concept.

Referring to FIG. 3, the method S1 of manufacturing a semiconductor package, according to an embodiment of the present inventive concept, may include first process S100 of forming a first structure, which includes the first semiconductor device 200 and the first redistribution structure 300, on each of two sides of a first double-sided attachment carrier DDC1, second process S200 of forming a second structure, which includes the second redistribution structure 400, on each of two sides of a second double-sided attachment carrier DDC2, and third process S300 of attaching the first structure and the second structure to each other and performing an additional process. First process S100, second process S200, and third process S300 are each described with reference to a flowchart of each process and cross-sectional views illustrating each process. Herein, a double-sided attachment carrier may be referred to as a detached copper foil (DCF) carrier.

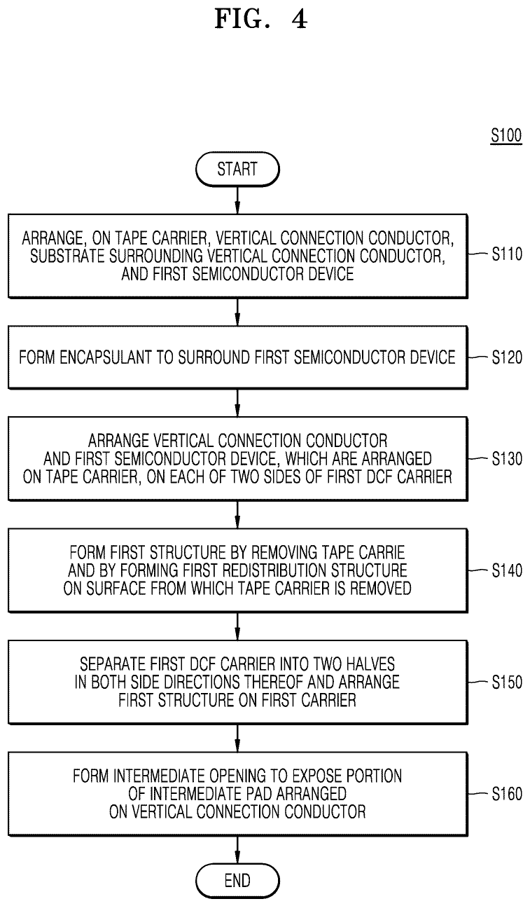

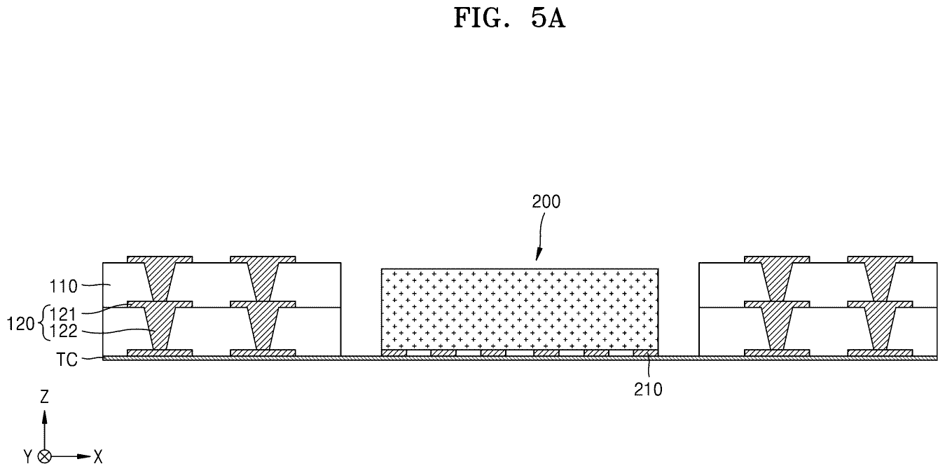

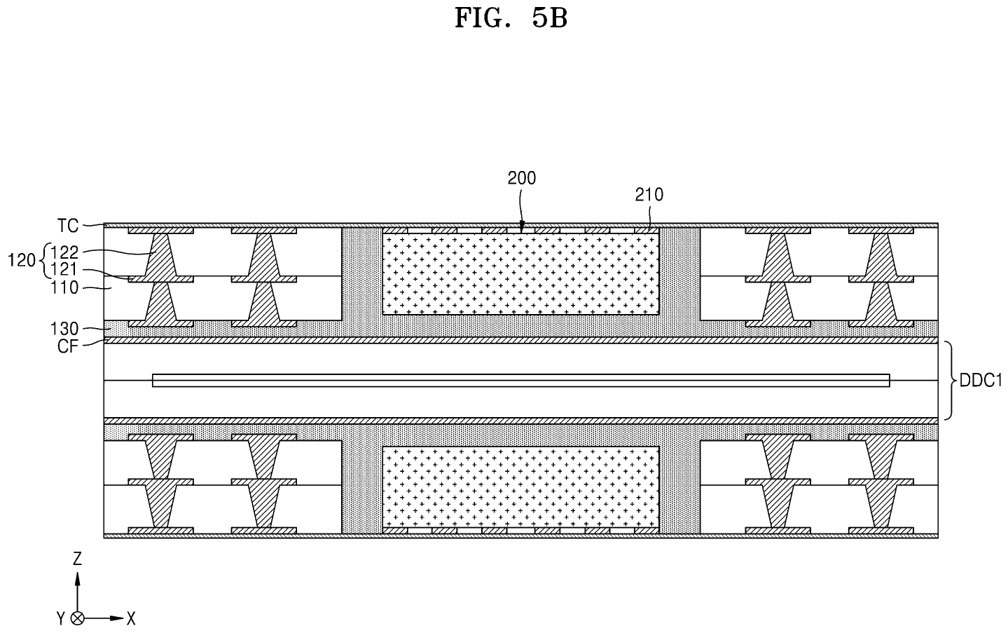

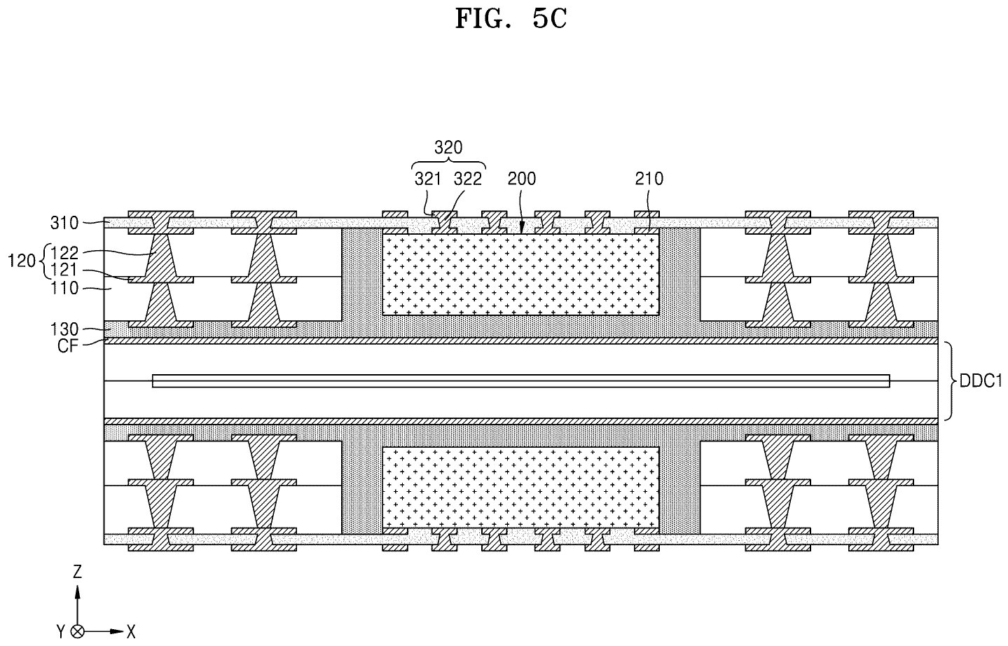

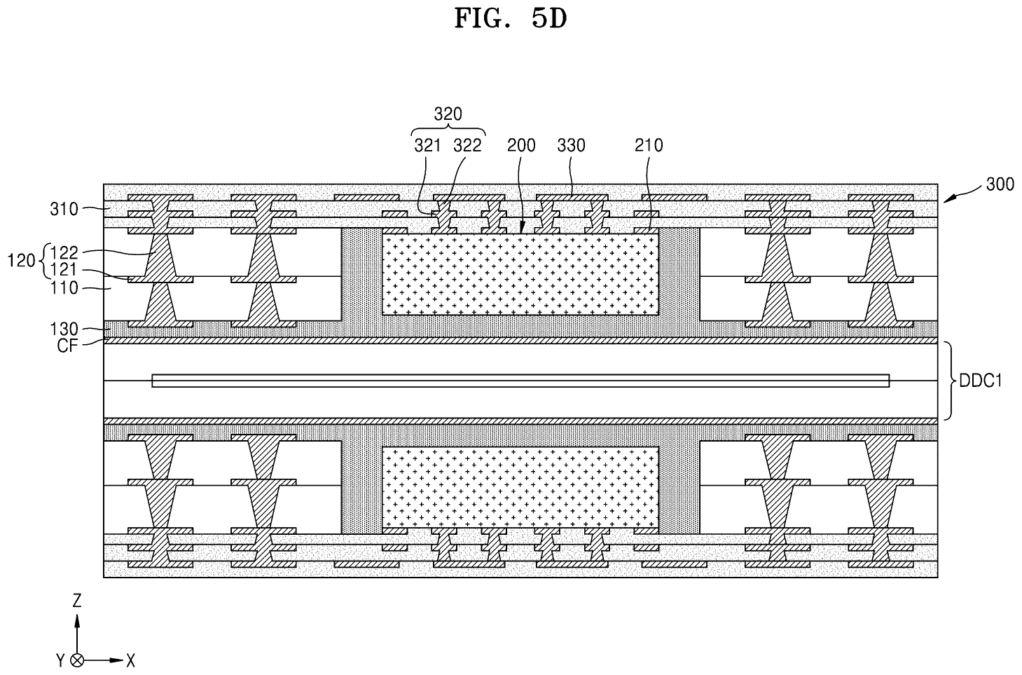

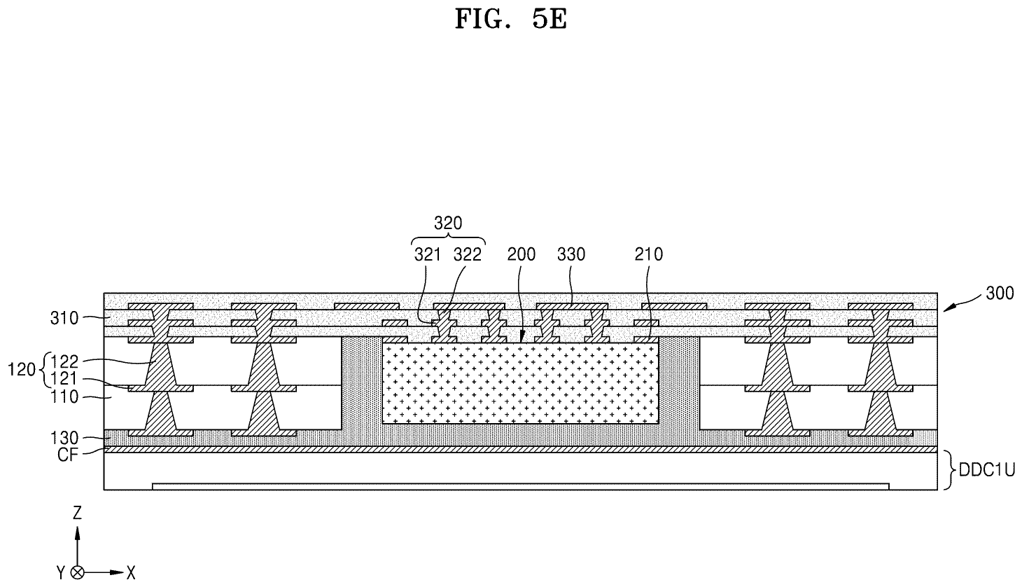

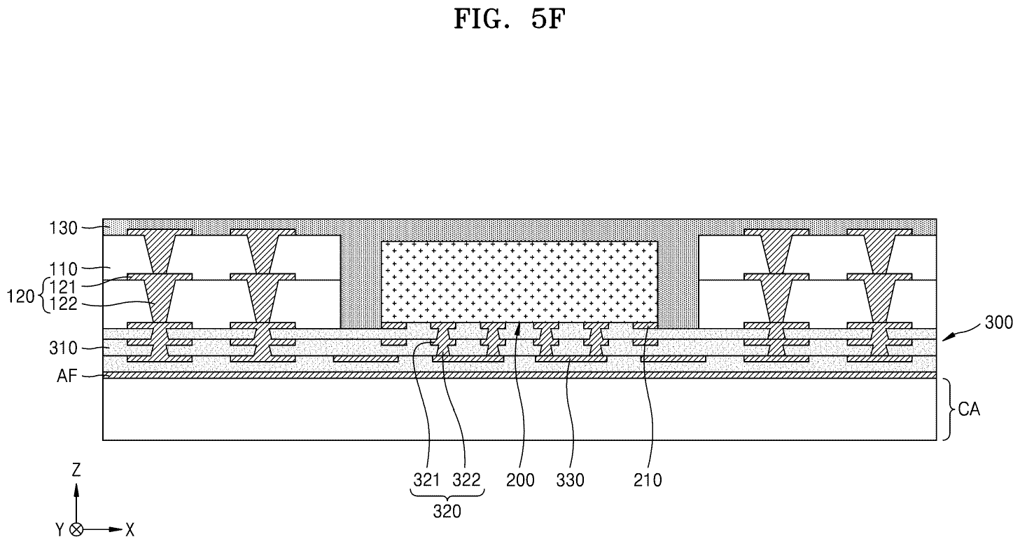

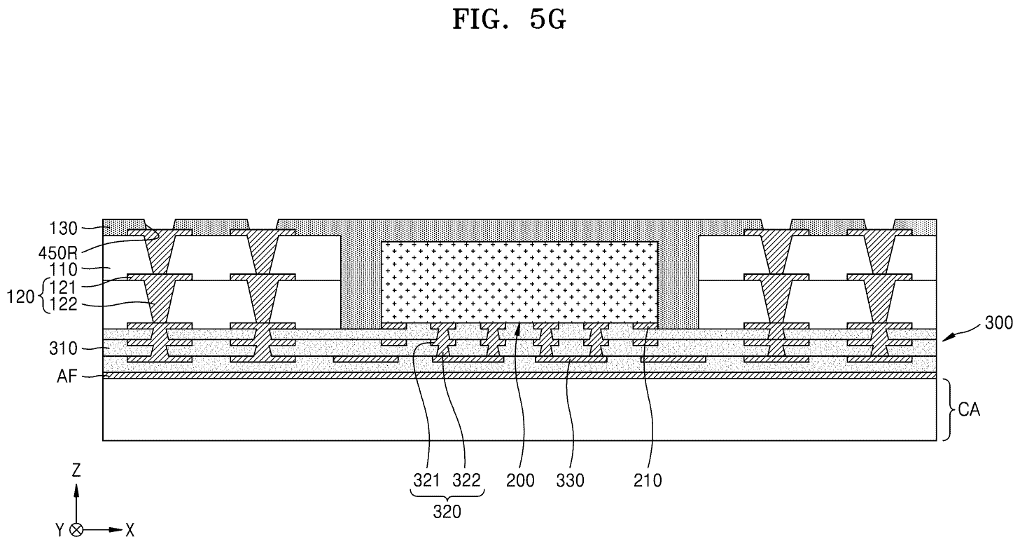

FIG. 4 is a flowchart illustrating first process S100 of the method S1 of manufacturing a semiconductor package, according to an embodiment of the present inventive concept. FIGS. 5A to 5G are cross-sectional views illustrating the first process S100 of the method S1 of manufacturing a semiconductor package, according to an embodiment of the present inventive concept. Repeated descriptions already given above may be omitted.

Referring to FIGS. 4 and 5A to 5G, first process S100 of the method S1 of manufacturing a semiconductor package, according to an embodiment of the present inventive concept, may include arranging, on a tape carrier TC, the wiring structure 120, the substrate base 110 surrounding the wiring structure 120 including the vertical connection conductor 122, and the first semiconductor device 200 (S110). The first process S100 further includes forming the encapsulant 130 to surround the first semiconductor device 200 (S120), and arranging the wiring structure 120, the substrate base 110, and the first semiconductor device 200, which are arranged on the tape carrier TC, on each of two sides of a first DCF carrier (S130). The first process S100 additionally includes forming a first structure by removing the tape carrier TC and by forming the first redistribution structure 300 on a surface from which the tape carrier TC is removed (S140), and separating the first double-sided attachment carrier DDC1 into two halves in both side directions of the first double-sided attachment carrier DDC1 and arranging the first structure on a first carrier CA (S150). In addition, the first process S100 includes forming the intermediate opening 450R in the encapsulant 130 to expose at least a portion of an intermediate connection pad that is on the vertical connection conductor 122 (S160).

Referring to FIG. 5A, the wiring structure 120, the substrate base 110, which includes the vertical connection conductor 122, and the first semiconductor device 200 may be arranged on the tape carrier TC. As described above, the substrate base 110 may be provided as a multilayered substrate including a plurality of substrate bases 110 as a plurality of layers. Each wiring pattern 121 may be formed between the plurality of substrate bases 110 and may be formed on at least some of the upper and lower surfaces of the plurality of substrate bases 110. The first semiconductor device 200 may be arranged in a cavity, which is formed in the substrate base 110, such that the active surface of the first semiconductor device 200 faces the tape carrier TC.

Referring to FIG. 5B, the encapsulant 130 may be formed to at least partially surround the first semiconductor device 200 and to partially surround the side and upper surfaces of the substrate base 110. After the encapsulant 130 is formed, planarization may be performed on the upper surface of the encapsulant 130. After the encapsulant 130 is formed, the process result product of FIG. 5A arranged on the tape carrier TC may be arranged on each of the two sides (e.g., opposing sides) of the first double-sided attachment carrier DDC1 by a DCF method. For example, as shown in FIG. 5B, due to a copper foil CF arranged on each of the two sides of the first double-sided attachment carrier DDC1, the encapsulant 130 may be arranged in the process result product of FIG. 5A to face the first double-sided attachment carrier DDC1. Due to the DCF method, because a larger number of process result products may be manufactured through one process, the efficiency of a semiconductor package manufacturing process may be increased.

The wiring structure 120, the substrate base 110, and the first semiconductor device 200, which are arranged on the tape carrier TC, may be arranged on each of the two sides of the first DCF carrier.

Referring to FIGS. 5C and 5D, the tape carrier TC that is located on each of the two sides of the first double-sided attachment carrier DDC1 may be removed, and the first redistribution structure 300 may be formed on the surface, from which the tape carrier TC is removed, for example, the surface on which the first semiconductor device 200 and the substrate base 110 are arranged. A process of forming the first redistribution structure 300 may be performed by a redistribution process, as described above. For example, by the redistribution process, the first redistribution insulating layer 310 and the first redistribution pattern 320, which includes the first redistribution via pattern 322 and the first redistribution line pattern 321, may be alternately formed, thereby forming the first redistribution structure 300. Herein, a semiconductor structure having undergone the processes until FIG. 5D and located on one side of the first double-sided attachment carrier DDC1 may be referred to as a first structure.

During the process of forming the semiconductor structure including the first semiconductor device 200, the warpage of the semiconductor structure may be generated. In the method S1 of manufacturing a semiconductor package, according to an embodiment of the present inventive concept, because first structures are respectively formed on both sides of a carrier by the DCF method, the first structures may be formed symmetrically to each other. Because the first structures having the same structure are respectively formed on both sides of the first double-sided attachment carrier DDC1, warpage on the first double-sided attachment carrier DDC1 due to the warpage generated in one first structure may be countervailed by the warpage of the other first structure located on the opposite side to the one first structure. For example, due to the first structures formed symmetrically to each other, the warpages of the first structures may be countervailed by each other, thereby preventing or reducing the warpage of the first double-sided attachment carrier DDC1. Therefore, because the first structure may be formed on the first double-sided attachment carrier DDC1 having better flatness, the reliability of the semiconductor package that includes the first structure may be increased.

Referring to FIG. 5E, the first double-sided attachment carrier DDC1 may be separated into a first upper attachment carrier DDCIU and a first lower carrier. The first structure, which are arranged on each of the two sides of the first double-sided attachment carrier DDC1, may be moved to the next process, after the first double-sided attachment carrier DDC1 is separated. In an embodiment of the present inventive concept, a subsequent process may be performed on the first structure that is arranged on the first upper attachment carrier DDCIU that is obtained by the separation of the first double-sided attachment carrier DDC1.

Referring to FIG. 5F, the first structure on the first upper attachment carrier DDCIU may be arranged on a carrier. For example, the first structure may be attached onto the first carrier CA via an attachment film AF. The first upper attachment carrier DDC1U, which is attached to the encapsulant 130 of the first structure on the first carrier CA, may be removed.

Referring to FIG. 5G, the intermediate opening 450R may be formed in at least a portion of the upper surface of the encapsulant 130 to expose at least a portion of the intermediate connection pad that is arranged on the vertical connection conductor 122.

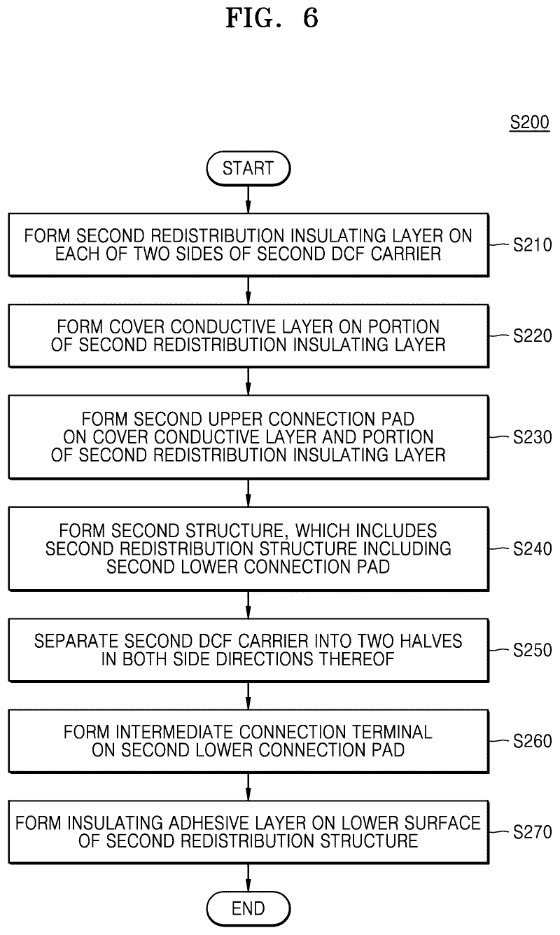

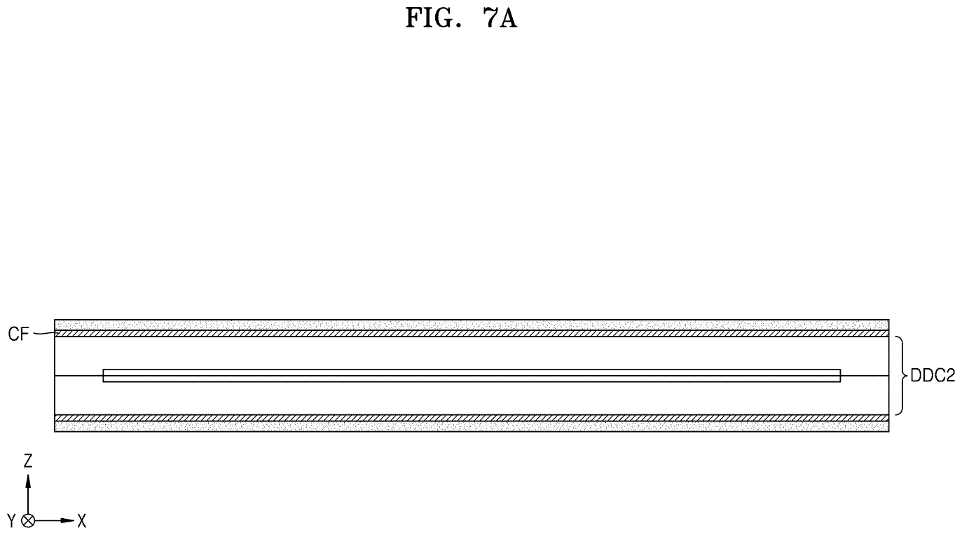

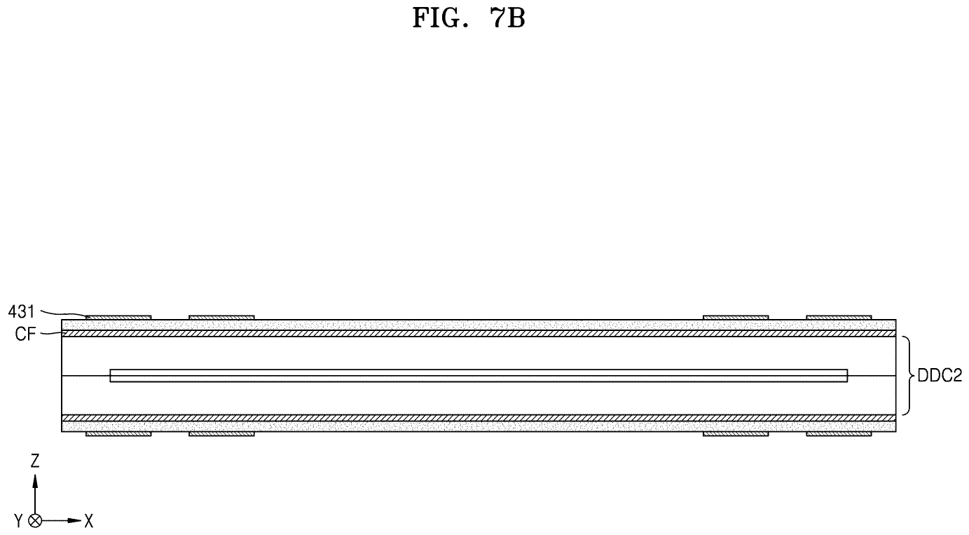

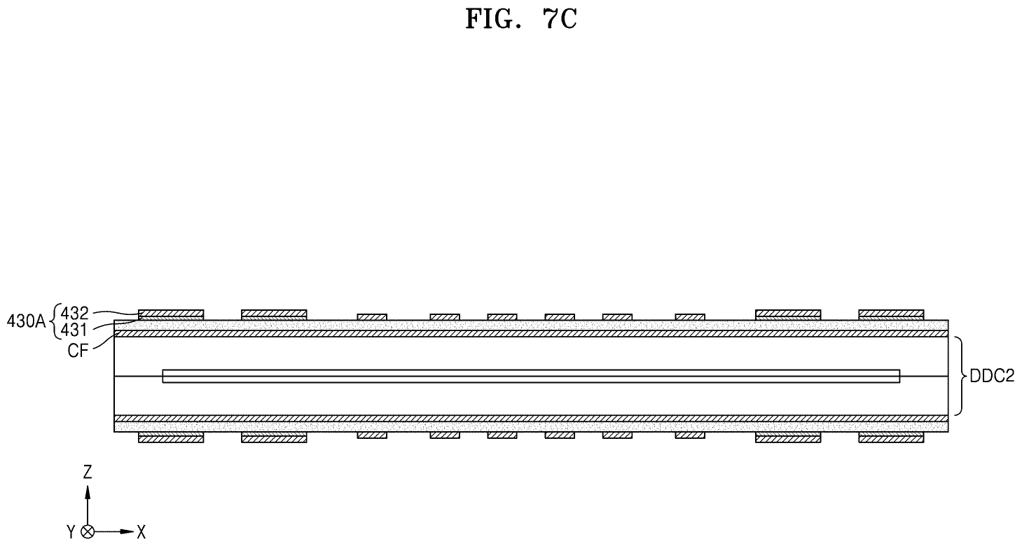

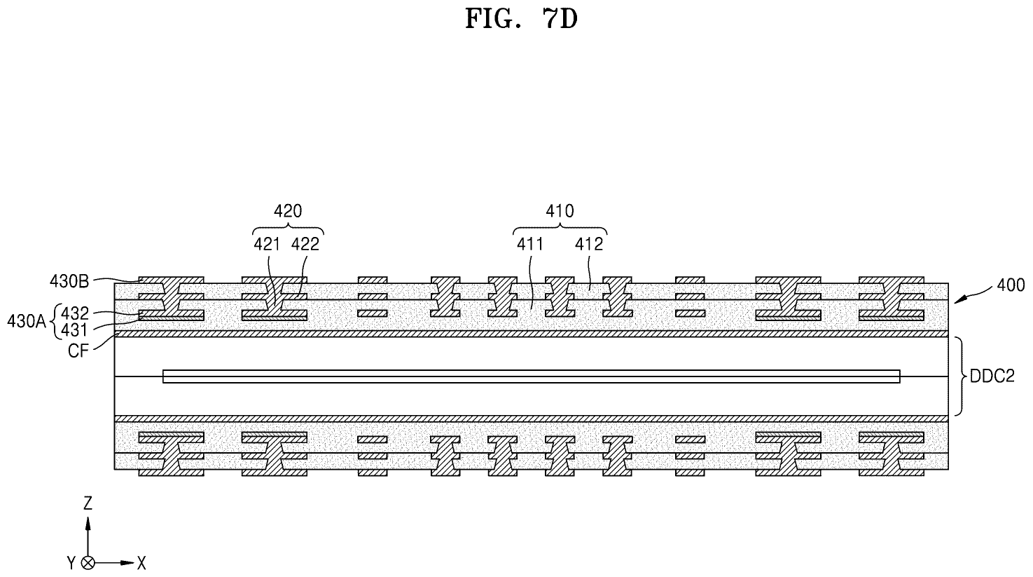

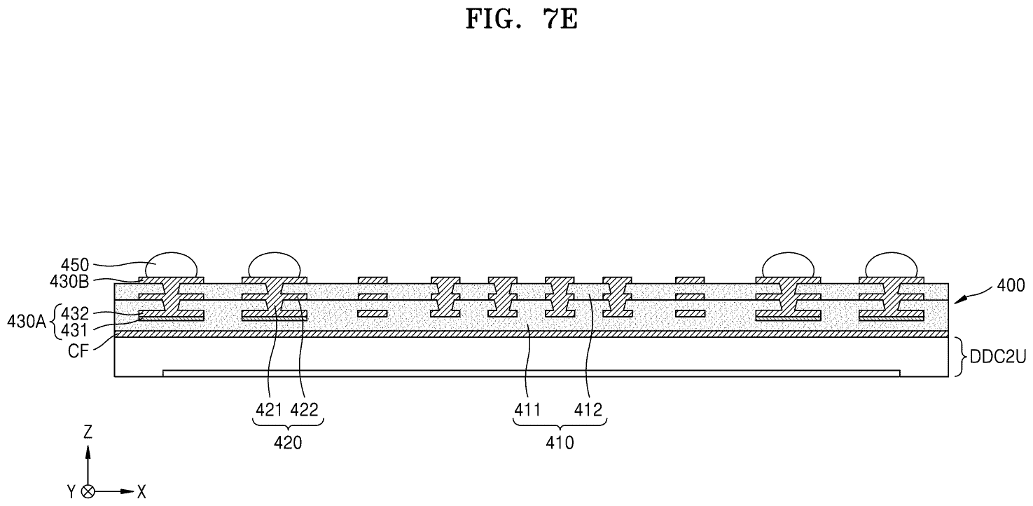

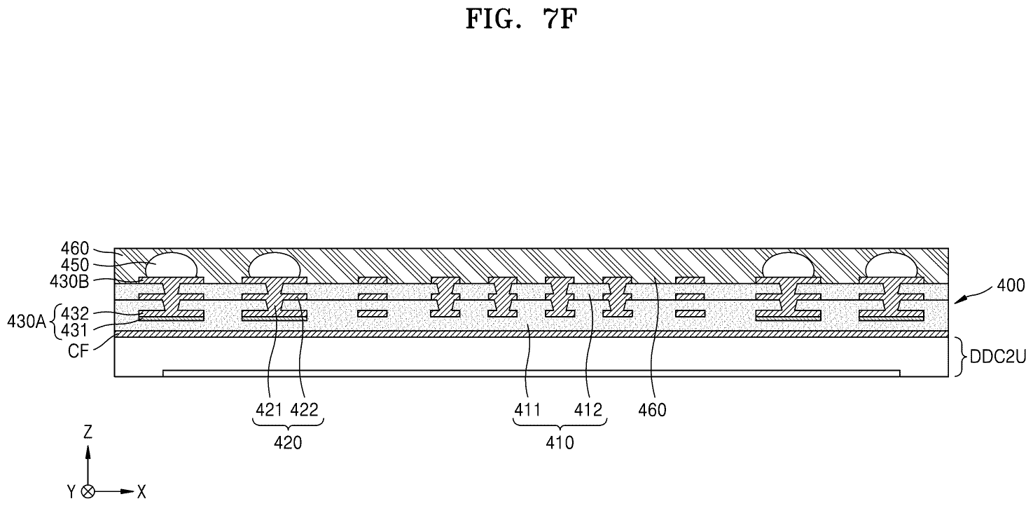

FIG. 6 is a flowchart illustrating second process S200 of the method S1 of manufacturing a semiconductor package, according to an embodiment of the present inventive concept. FIGS. 7A to 7F are cross-sectional views illustrating the second process S200 of the method S1 of manufacturing a semiconductor package, according to an embodiment of the present inventive concept. Repeated descriptions already given above may be omitted or briefly discussed.

Referring to FIG. 6, second process S200 of the method S1 of manufacturing a semiconductor package, according to an embodiment of the present inventive concept, may include forming the second redistribution insulating layer 410 on each of two sides of a second double-sided attachment carrier DDC2 (S210), and forming the cover conductive layer 431 on a portion of the second redistribution insulating layer 410 (S220). The second process S200 may further include forming the second upper connection pad 430A on the cover conductive layer 431 and a portion of the second redistribution insulating layer 410 (S230), and forming a second structure including the second redistribution structure 400 that includes the second lower connection pad 430B (S240). The second process S200 additionally includes separating the second double-sided attachment carrier DDC2, which includes the second structure on each of the two sides thereof, into two halves in both side directions of the second double-sided attachment carrier DDC2 (S250), and forming the intermediate connection terminal 450 on the second lower connection pad 430B (S260). In addition, the second process S200 includes forming the insulating adhesive layer 460 on the lower surface of the second redistribution structure 400 (S270).

Referring to FIG. 7A, the second redistribution insulating layer 410 may be formed as one layer on each of the two sides of the second double-sided attachment carrier DDC2.

Referring to FIG. 7B, the cover conductive layer 431 may be formed on each of the two sides of the second double-sided attachment carrier DDC2, on which the second redistribution insulating layer 410 is formed. The cover conductive layer 431 may be formed by, for example, electroplating.

Referring to FIG. 7C, the second redistribution line pattern 422 may be formed on the second redistribution insulating layer 410 and the second connection pad pattern 432 may be formed on the cover conductive layer 431, thereby forming the second upper connection pad 430A, which includes the cover conductive layer 431 and the second connection pad pattern 432. According to the method S1 of manufacturing a semiconductor package, according to an embodiment of the present inventive concept, due to a process sequence allowing the cover conductive layer 431 to be formed earlier than the second connection pad pattern 432, when the second upper connection pad 430A of the semiconductor package 1, which is manufactured by the method S1 of manufacturing a semiconductor package, is connected with the outside of the semiconductor package 1, the cover conductive layer 431 is in contact and connected with the outside of the semiconductor package 1, and thus, the electrical conductivity of the semiconductor package 1 may be increased.

Referring to FIG. 7D, in the process result product of FIG. 7C, the second redistribution structure 400 may be formed on each of the two sides of the second double-sided attachment carrier DDC2. Herein, a structure including the second redistribution structure 400 in addition to the process result product of FIG. 7C may be referred to as a second structure.

Referring to FIGS. 7E and 7F, the second double-sided attachment carrier DDC2 may be separated into a second upper attachment carrier DDC2U and a second lower attachment carrier. The second structure, which is arranged on each of the two sides of the second double-sided attachment carrier DDC2, may be moved to the next process, after the second double-sided attachment carrier DDC2 is separated. In an embodiment of the present inventive concept, a subsequent process may be performed on the second structure, which is arranged on the second upper attachment carrier DDC2U obtained by the separation of the second double-sided attachment carrier DDC2.

Like first process S100 described above, in the method S1 of manufacturing a semiconductor package, according to an embodiment of the present inventive concept, the second structures are formed respectively on both sides of a carrier by the DCF method. Therefore, due to the second structures formed symmetrically to each other, the warpages of the second structures may be countervailed by each other, thereby preventing or reducing the warpage of the second double-sided attachment carrier DDC2. Therefore, because the second structure may be formed on the second double-sided attachment carrier DDC2 having better flatness, the reliability of the semiconductor package including the second structure may increase. In addition, due to the DCF method, because a larger number of process result products may be manufactured through one process, the efficiency of a semiconductor package manufacturing process may be increased.

The intermediate connection terminal 450 may be formed on the second structure, which is arranged on the second upper attachment carrier DDC2U that is separated, and the insulating adhesive layer 460 may be formed on the lower surface of the second redistribution structure 400.

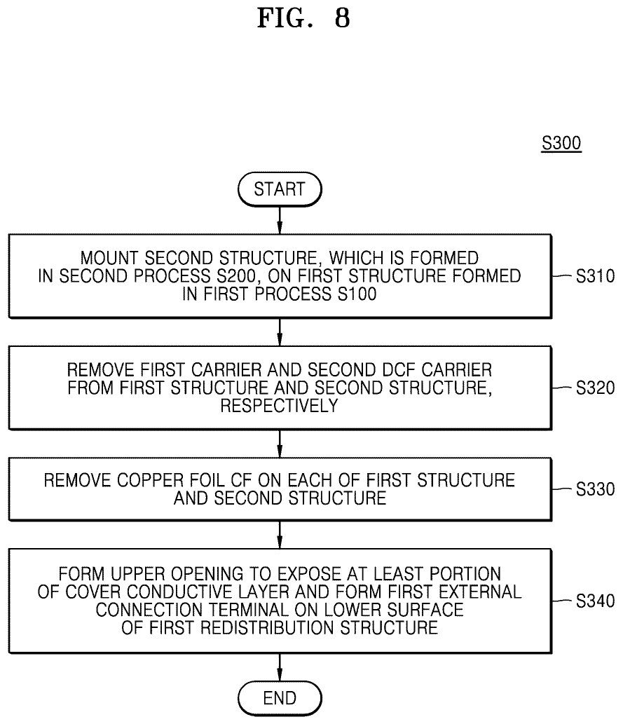

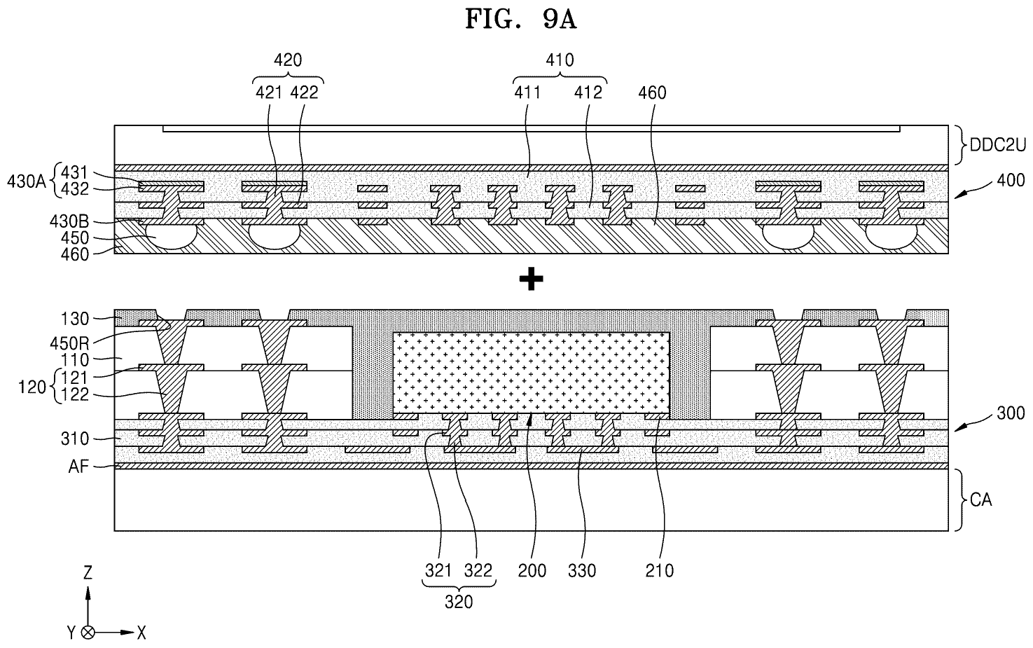

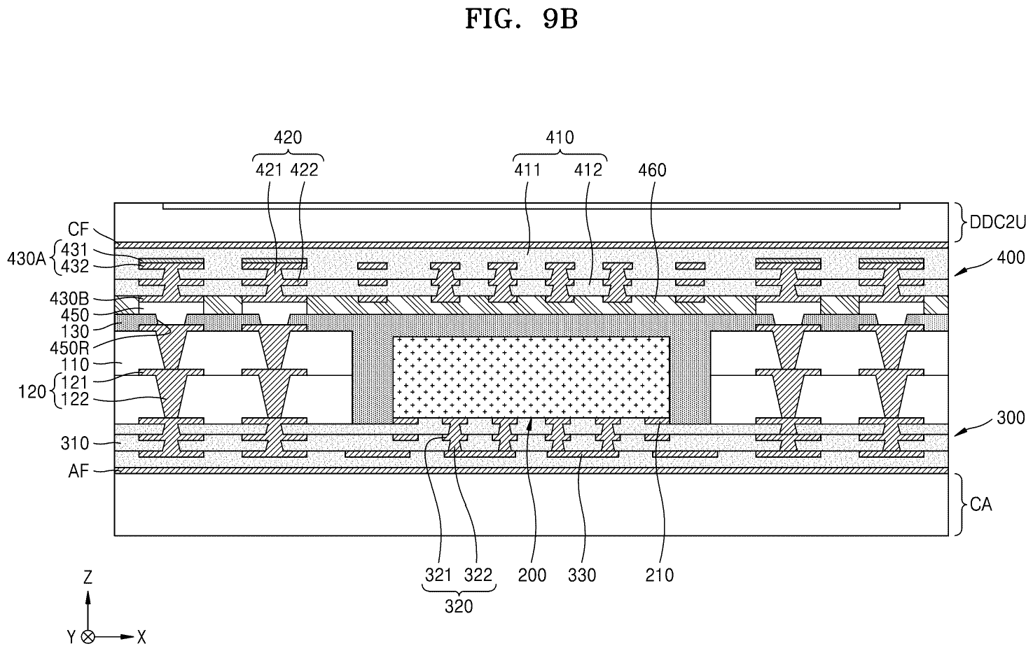

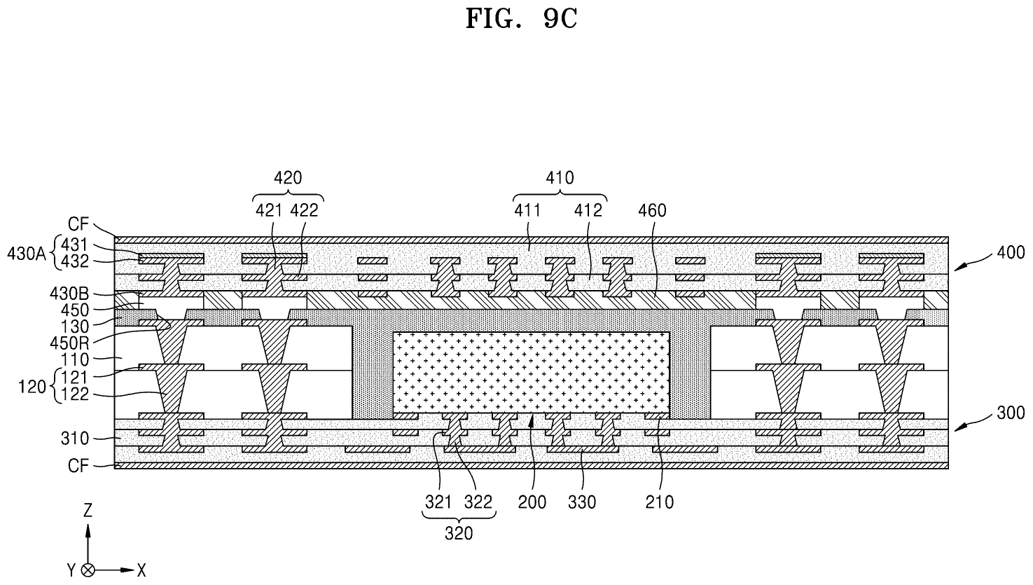

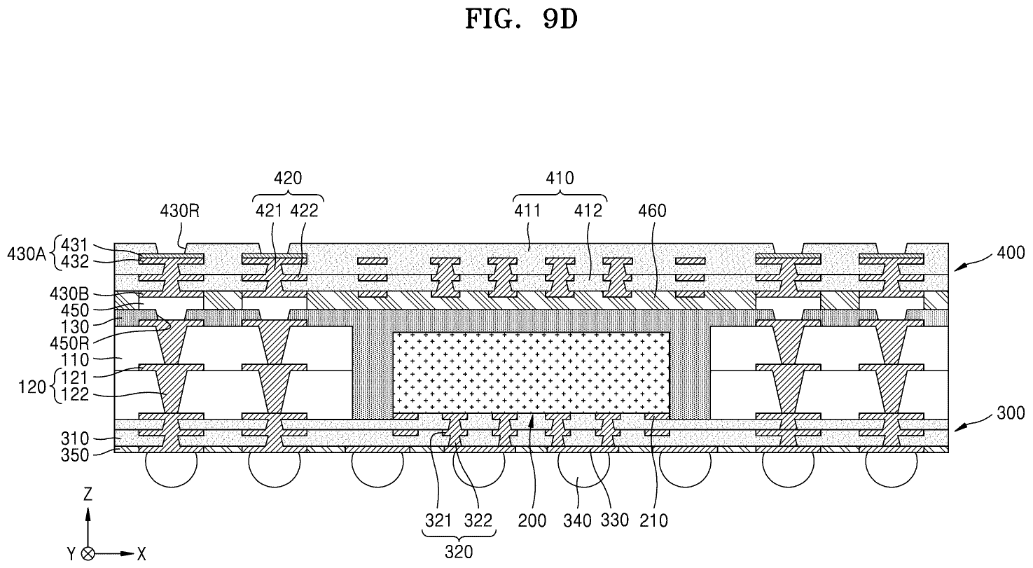

FIG. 8 is a flowchart illustrating third process S300 of the method S1 of manufacturing a semiconductor package, according to an embodiment of the present inventive concept. FIGS. 9A to 9D are cross-sectional views illustrating third process S300 of the method S1 of manufacturing a semiconductor package, according to an embodiment of the present inventive concept.

Referring to FIG. 8, third process S300 of the method S1 of manufacturing a semiconductor package, according to an embodiment of the present inventive concept, may include mounting the second structure, which is formed in second process S200, on the first structure, which is formed in first process S100 (S310), and removing the first carrier CA and the second double-sided attachment carrier DDC2 from the first structure and the second structure, respectively (S320). The third process S300 may further include removing the copper foil CF on each of the first structure and the second structure (S330), and forming the upper opening 430R to expose at least a portion of the cover conductive layer 431 and forming the first external connection terminal 340 on the lower surface of the first redistribution structure 300 (S340).

Referring to FIGS. 9A and 9B, the second structure, which is a resulting product obtained through second process S200, may be attached onto the first structure, which is a resulting product obtained through first process S100. As shown in FIG. 9A, in a process of attaching the second structure to the first structure, the first structure and the second structure may be attached to each other while the first structure is arranged on the first carrier CA and the second structure is arranged on the second upper attachment carrier DDC2U.

As described above, because thermocompression bonding between the first structure and the second structure is performed via a low-temperature solder ball having a melting point of about 200° C. or less or a conductive paste, which corresponds to the intermediate connection terminal 450, the warpage of each of the first structure and the second structure may be reduced as compared with general thermocompression bonding performed at a higher temperature. In addition, because the attachment between the first structure and the second structure is performed while the first structure is arranged on the first carrier CA, and the second structure is arranged on the second upper attachment carrier DDC2U, the consistency of the attachment between the first structure and the second structure may be secured. Therefore, the reliability of the semiconductor package 1 according to an embodiment may be increased.

As shown in FIG. 9B, the insulating adhesive layer 460 may be arranged between the second redistribution structure 400 and the first structure including the encapsulant 130 and may attach the first structure and the second structure to each other. In addition, during the process of attaching the first structure and the second structure to each other, at least a portion of the intermediate connection terminal 450 may be formed with a shape corresponding to the shape of the intermediate opening 450R that is formed in the encapsulant 130.

Referring to FIG. 9C, after the first structure and the second structure are attached to each other, the first carrier CA and the second upper attachment carrier DDC2U may be removed.

Referring to FIG. 9D, the copper foil CF, which is attached to each of the first structure and the second structure, may be removed from the first structure and the second structure. In addition, the lowermost first redistribution insulating layer 310 of the first redistribution structure 300 may be partially removed by, for example, laser processing, thereby exposing the external connection pad 330 so that the external connection terminal 340 can be attached to the external connection pad 330. In addition, the protective layer 350 may be formed on the lower surface of the first redistribution structure 300. The external connection terminal 340 may be formed on the external connection pad 330.

According to the method S1 of manufacturing a semiconductor package, according to an embodiment of the present inventive concept, because first process S100 and second process S200 are performed separately from each other, the turn-around time of the production of a semiconductor package may be reduced. In addition, due to the DCF method, each of the first structure and the second structure may be manufactured on each of two sides of a double-sided attachment carrier, and thus, the productivity of the semiconductor package 1 may be increased.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A semiconductor package comprising:
a first redistribution structure, which comprises a first upper connection pad and a first lower connection pad, wherein the first upper connection pad is disposed on an upper surface of the first redistribution structure, and wherein the first lower connection pad is disposed on a lower surface of the first redistribution structure;
a first semiconductor device mounted on the first redistribution structure;
a vertical connection conductor, which is spaced apart from the first semiconductor device and arranged on the first redistribution structure;
an encapsulant at least partially surrounding the first semiconductor device;
a second redistribution structure arranged on the encapsulant and comprising a second redistribution pattern and a second insulating layer, wherein the second redistribution structure further comprises a second upper connection pad and a second lower connection pad, wherein the second upper connection pad is disposed on an upper surface of the second redistribution structure, and the second lower connection pad is disposed on a lower surface of the second redistribution structure;
an insulating adhesive layer arranged between the second redistribution structure and the encapsulant, which are apart from each other; and
an intermediate connection terminal connecting the second lower connection pad with the vertical connection conductor,
wherein at least a portion of the second upper connection pad is exposed from the second insulating layer by an upper opening of the second insulating layer,
a cover conductive layer is arranged on the second upper connection pad,
a portion of a side surface of the intermediate connection terminal is covered with the insulating adhesive layer, and
the remaining portion of the side surface of the intermediate connection terminal is covered with the encapsulant.

2. The semiconductor package of claim 1, wherein the insulating adhesive layer comprises a nonconductive film or a nonconductive adhesive.

3. The semiconductor package of claim 2, wherein the first redistribution structure comprises a first redistribution pattern and a first redistribution insulating layer,
the first redistribution pattern comprises a first redistribution line pattern and a first redistribution via pattern, and
a horizontal width of the first redistribution via pattern increases between a top portion and a bottom portion of the first redistribution via pattern.

4. The semiconductor package of claim 3, wherein the second redistribution pattern comprises a second redistribution line pattern and a second redistribution via pattern, and
a horizontal width of the second redistribution via pattern increases between a top portion and a bottom portion of the first redistribution via pattern.

5. The semiconductor package of claim 4, wherein the intermediate connection terminal comprises a low-temperature solder ball or a conductive paste, which electrically and connects the vertical connection conductor and the second redistribution structure to each other,
each of the low-temperature solder ball and the conductive paste has a melting point of about 200° C. or less,
the low-temperature solder ball comprises tin (Sn), bismuth (Bi), and zinc (Zn), and
the conductive paste comprises silver (Ag) and a thermosetting resin.

6. The semiconductor package of claim 5, wherein the first semiconductor device is in contact with the first redistribution insulating layer.

7. The semiconductor package of claim 5, wherein at least a portion of the cover conductive layer of the second upper connection pad is exposed by the upper opening of the second insulating layer, and
the second upper connection pad is surrounded by the second insulating layer and the cover conductive layer.

8. The semiconductor package of claim 7, wherein the cover conductive layer comprises a plurality of plating layers, wherein at least one plating layer comprises gold (Au), and another plating layer comprises nickel (Ni).

9. The semiconductor package of claim 8, wherein the encapsulant comprises an intermediate opening, which is filled with at least a portion of the intermediate connection terminal, and a horizontal width of the intermediate opening increases as the second redistribution structure is approached.

10. The semiconductor package of claim 9, further comprising a second semiconductor device mounted on the second redistribution structure.

11. A method of manufacturing a semiconductor package, the method comprising:
a first process comprising:
forming a first structure, which comprises a first semiconductor device and a first redistribution structure, on each of two sides of a first detached copper foil (DCF) carrier; and
separating the first DCF carrier into two halves in both side directions of the first DCF carrier;
a second process comprising:
forming a second structure, which comprises a second redistribution structure, on each of two sides of a second DCF carrier; and
separating the second DCF carrier into two halves in both side directions of the second DCF carrier; and
a third process comprising attaching the first structure and the second structure to each other.

12. The method of claim 11, wherein the first process comprises:
arranging, on a tape carrier, a vertical connection conductor, a substrate base, which surrounds the vertical connection conductor, and a first semiconductor device that is laterally spaced apart from the substrate base;
forming an encapsulant that at least partially surrounds the first semiconductor device;
arranging the vertical connection conductor and the first semiconductor device, which are arranged on the tape carrier, on each of the two sides of the first DCF carrier;
forming the first structure, which comprises the first semiconductor device and the first redistribution structure, on each of the two sides of the first DCF carrier by removing the tape carrier and by forming the first redistribution structure on a surface from which the tape carrier is removed;
separating the first DCF carrier into two halves in both side directions of the first DCF carrier and arranging the first structure on a first carrier; and
forming an intermediate opening in the encapsulant to expose a portion of an intermediate pad, which is arranged on the vertical connection conductor.

13. The method of claim 12, wherein the second process comprises:
forming the second structure, which comprises the second redistribution structure comprising a second lower connection pad, on each of the two sides of the second DCF carrier;
separating the second DCF carrier into two halves in both side directions of the second DCF carrier;
forming an intermediate connection terminal on the second lower connection pad; and
forming an insulating adhesive layer on a lower surface of the second redistribution structure.

14. The method of claim 13, wherein the forming of the second structure comprises:
forming a second redistribution insulating layer on each of the two sides of the second DCF carrier;
forming a cover conductive layer on a portion of the second redistribution insulating layer;
forming a second upper connection pad pattern on the cover conductive layer and a portion of the second redistribution insulating layer; and
forming the second redistribution structure.

15. The method of claim 13, wherein the third process comprises:
mounting the second structure on the first structure;
removing the first carrier and the second DCF carrier from the first structure and the second structure, respectively; and
removing a copper foil that is on each of the first structure and the second structure.

16. The method of claim 15, wherein the third process further comprises:
after the removing of the copper foil,
forming an upper opening to expose at least a portion of the cover conductive layer of the second upper connection pad, by recessing a portion of an upper surface of the second redistribution structure; and
forming a first external connection terminal on a lower surface of the first redistribution structure.

17. The method of claim 15, wherein the intermediate connection terminal comprises a low-temperature solder ball or a conductive paste, which electrically connects the vertical connection conductor and the second redistribution structure to each other,
each of the low-temperature solder ball and the conductive paste electrically connects the vertical connection conductor and the second redistribution structure to each other by a thermocompression process performed at a temperature that is less than or equal to a melting point of a material constituting the insulating adhesive layer,
each of the low-temperature solder ball and the conductive paste has a melting point of about 200° C. or less,
the low-temperature solder ball comprises tin (Sn), bismuth (Bi), and zinc (Zn), and
the conductive paste comprises silver (Ag) and a thermosetting resin.

18. The method of claim 16, wherein the cover conductive layer comprises a plurality of plating layers, wherein at least one plating layer comprises gold (Au), and another plating layer comprises nickel (Ni).

19. A method of manufacturing a semiconductor package, the method comprising:
a first process comprising:
forming a first structure, which comprises a first semiconductor device and a first redistribution structure, on each of two sides of a first detached copper foil (DCF) carrier; and
separating the first DCF carrier into two halves in different directions of each other;
a second process comprising:
forming a second structure, which comprises a second redistribution structure, on each of two sides of a second DCF carrier; and
separating the second DCF carrier into two halves in different directions of each other; and
a third process of attaching the first structure and the second structure to each other,
wherein the first process further comprises:
arranging, on a tape carrier, a vertical connection conductor, a substrate base, which surrounds the vertical connection conductor, and a first semiconductor device that is laterally spaced apart from the substrate base;
forming an encapsulant that at least partially surrounds the first semiconductor device;
arranging the vertical connection conductor and the first semiconductor device, which are arranged on the tape carrier, on each of the two sides of the first DCF carrier;
forming the first structure, which comprises the first semiconductor device and the first redistribution structure, on each of the two sides of the first DCF carrier by removing the tape carrier and by forming the first redistribution structure on a surface from which the tape carrier is removed;
separating the first DCF carrier into two halves in different directions of each other and arranging the first structure on a first carrier; and
forming an intermediate opening in the encapsulant by recessing the encapsulant, wherein the intermediate opening exposes a portion of a wiring pattern that is arranged on the vertical connection conductor,
wherein the second process further comprises:
forming a second redistribution insulating layer on each of the two sides of the second DCF carrier;
forming a cover conductive layer on a portion of the second redistribution insulating layer;
forming a second upper connection pad pattern on the cover conductive layer and a portion of the second redistribution insulating layer;
forming the second redistribution structure;
separating the second DCF carrier into two halves in different directions of each other;
forming an intermediate connection terminal on the second lower connection pad; and
forming an insulating adhesive layer on a lower surface of the second redistribution structure,
and wherein the third process further comprises:
mounting the second structure on the first structure;
removing the first carrier and the second DCF carrier from the first structure and the second structure, respectively;
removing a copper foil that is on each of the first structure and the second structure;
forming an upper opening by recessing a portion of an upper surface of the second redistribution structure, wherein the upper opening exposes at least a portion of the cover conductive layer; and
forming a first external connection terminal on a lower surface of the first redistribution structure.

20. The method of claim 19, wherein the intermediate connection terminal comprises a low-temperature solder ball or a conductive paste, which electrically connects the vertical connection conductor and the second redistribution structure to each other,
each of the low-temperature solder ball and the conductive paste electrically connects the vertical connection conductor and the second redistribution structure to each other by a thermocompression process performed at a temperature that is less than or equal to a melting point of a material constituting the insulating adhesive layer,
each of the low-temperature solder ball and the conductive paste has a melting point of about 200° C. or less,
the low-temperature solder ball comprises tin (Sn), bismuth (Bi), and zinc (Zn), and
the conductive paste comprises silver (Ag) and a thermosetting resin.
